(19) United States
(12) Patent Application Publication
(10) Pub. No.: US 2002/0045304 A1
(43) Pub. Date: Apr. 18, 2002

(54) Fabrication method and structure of flash memory device

(76) Inventor: Chien-Hsing Lee, Chupei City (TW)

Correspondence Address: J.C. Patents, Suite 250, 4 Venture, Irvine, CA, 92618, US

(21) Appl. No.: 09/972,454

(22) Filed: Oct. 3, 2001

Related U.S. Application Data
(62) Division of application No. 09/475,009, filed on Dec. 30, 1999.

(51) Int. Cl. H01L 21/8238

(52) U.S. Cl. 438/201

(57) ABSTRACT

A method for fabricating a flash memory device is described in which a substrate is provided. A gate oxide layer and its overlying floating gate are formed on the substrate. A cap layer is formed on the floating gate, and a spacer is formed on the sidewalls of the cap layer, the floating gate and the gate oxide layer. Thereafter, trenches are formed in the exposed substrate that is not covered by the cap layer and the spacer. Source/drain regions are then formed in the substrate at the bottom of the trenches. Subsequently, the cap layer and the spacer are removed and a conformal first dielectric layer is formed on the substrate. A conductive layer is further formed on the substrate.

### BACKGROUND OF THE INVENTION

1. Field of the Invention

The present invention relates to a structure and a fabrication method for a flash memory device. More particularly, the present invention relates to a structure and a fabrication method for a split-gate flash memory device.

2. Description of the Related Art

In general, the conventional structure of an erasable programmable read-only memory (EPROM) device is similar to that of the N-type metal-oxide-semiconductor (MOS), wherein the gate structure is the stacked gate type, comprising a polysilicon floating gate for charge storage, and a control gate to control the storage and retrieval of information. Thus a typical EPROM unit comprises two gates, a floating gate and the underlying control gate. The control gate is connected to the word line, while the floating gate is maintained in a “floating” condition and has no connection with the external circuits. Currently, the most popular type of the flash memory device, developed by Intel corporation, can conduct erasure operations “block-by-block”, and the erasure speed is fast. The erasure operation is completed in 1 to 2 seconds, greatly reducing the time and the cost of operation. The traditional stacked gate structure of the flash memory device, wherein the floating gate and the control gate are stacked on each other, often results in the problem of an over-erasure during the flash-memory device erasure operation.

To resolve the over-erasure problem in the traditional stacked gate structure of a flash memory device, a split gate flash memory device is being developed.

FIG. 1 is a schematic, cross-sectional view of a split-gate flash-memory device according to the prior art. The structure of the split-gate flash memory device includes a substrate 100, comprising a source region 102a and a drain region 102b. On the substrate 100 is a gate oxide layer 104, wherein a floating gate 106, a dielectric layer 108 and a control gate 110 are on the gate oxide layer 104.

The conventional flash memory device is formed by forming a source region 102a and a drain region 102b, respectively in the substrate 100. A dielectric layer (not shown) and a conductive layer (not shown) are formed on the substrate 100, immediately followed by a definition of the conductive layer and the dielectric layer to form a floating gate 106 and a gate oxide layer 104, respectively. The gate oxide layer 104 is formed on the substrate 100 at a side of the source region 102a or the drain region 102b, partially covering either the source region 102a or the drain region 102b.

The operation conditions of a conventional split-gate flash-memory device are summarized in Table 1.

TABLE 1
Operation Conditions of a Conventional Split-Gate Flash-Memory Device.

| | Control | Bit Line | | |
|---|---|---|---|---|
| Operations | Gate | (Drain Region) | Source Region | Substrate |
| Programming | 8-12 V | 3-8 V | GND | GND |
| Erasure | GND | GND | GND | >15 V |
| Reading | Vcc | 1-2 V | GND | GND |

In a split gate flash memory device, the control gate 110 and the floating gate 106 are not completely stacked on each other, the problem of an excessive erasure as in the conventional stacked gate is thereby obviated. As the device dimensions are continuously being reduced, the distance between the source region 102a and the drain region 102b, however, also decreases. A short channel between the source region 102a and the drain region 102b thus results, easily leading to the through effect. The dimensions of a split-gate flash-memory device, as a result, cannot be scaled-down.

Furthermore, during the programming operation of the traditional split-gate flash-memory device, hot electrons travel from the source region 102a to the drain region 102b and along the border of the drain region 102b to vertically penetrate through the gate oxide layer 104 and inject into the floating gate 106. The hot electrons are injected into floating gate 106a at only one hot carrier injection point as indicated by the arrow 112. The split-gate flash-memory device thus suffers a high program current consumption and low electron injection efficiency. Consequently, the operating speed of the flash memory device cannot be increased.

### SUMMARY OF THE INVENTION

Based on the foregoing, the current invention provides a fabrication method for a flash memory device wherein a substrate is provided. A gate oxide layer and an overlying floating gate are formed on the substrate, wherein the floating gate comprises a cap layer. A spacer is further formed on the sidewalls of the cap layer, the floating gate and the gate oxide layer. Thereafter, trenches are formed in the exposed substrate not covered by the spacer and the cap layer. Source/drain regions are then formed at the bottom of the trenches in the substrate. The cap layers and the spacers are subsequently removed, followed by forming a conformal dielectric layer on the substrate. After this, a conductive layer is formed on the substrate.

The present version of the current invention provides a structure of a flash memory device, which includes a substrate, a gate oxide layer, a floating gate, source/drain regions, a dielectric layer and a control gate, wherein the substrate comprises at least two trenches. The gate oxide layer is situated between the trenches on the substrate and the floating gate is located on the gate oxide layer. The source/drain regions are positioned in the substrate at the bottom the trenches, whereas the dielectric layer on the substrate conformably covers the floating gate, the gate oxide layer and the trenches. A control gate is also located on the dielectric layer. Additionally, the trenches are about 0.1 micron to 1 micron deep. The source/drain regions, which are positioned at both sides of the floating gate, form a symmetrical structure.

Since the floating gate and the corresponding source/drain regions at both sides of the floating gate forms a symmetrical structure, the probability of the hot carriers to be injected into the floating gate from the two source/drain regions are about equal. Two hot carrier injection points are thus formed underneath the floating gate, greatly reducing the programming current consumption and enhancing the efficiency of the hot carrier injection. The operating speed of the flash memory cell is thus increased. Furthermore, since the depth of the trenches is about equal to the channel length of the split gate transistor, the channel length of the split gate transistor will not be affected by the shrinkage of the device dimensions.

Furthermore, because the source/drain regions are formed in the substrate after the formation of the floating gate, the method of forming the floating gate thus has a greater processing window.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a schematic, cross-sectional view of a split-gate flash memory device according to the prior art; and

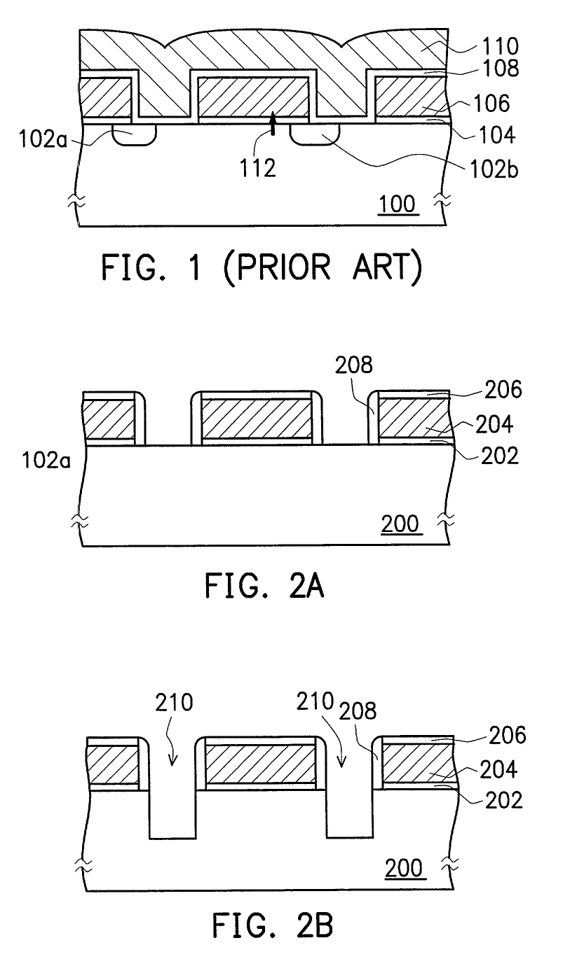

FIGS. 2A to 2F are schematic, cross-sectional views of a flash memory device according to the present invention.

FIG. 2G is a cross-sectional view of FIG. 2F along the line I-I.

### DESCRIPTION OF THE PREFERRED EMBODIMENT

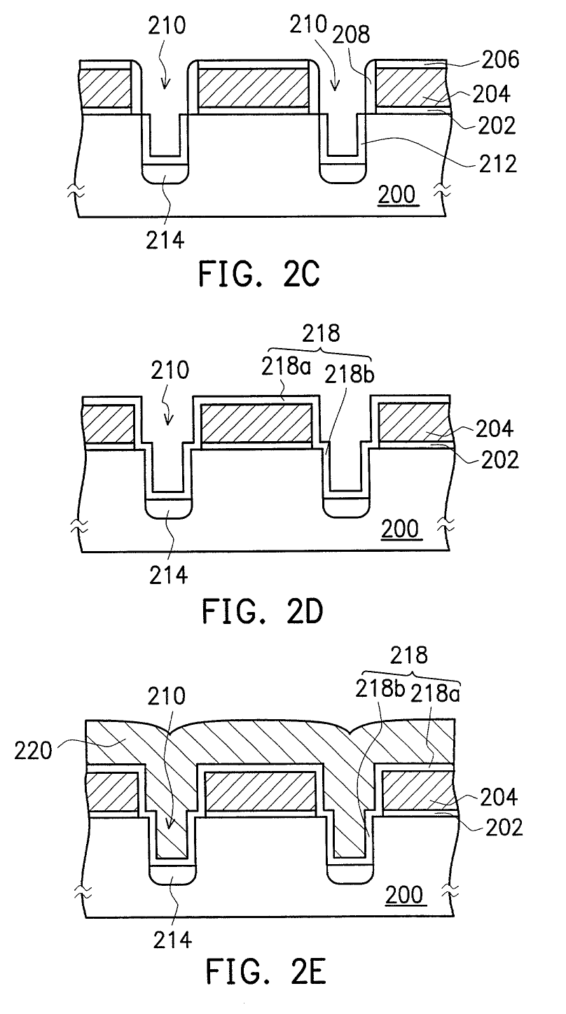

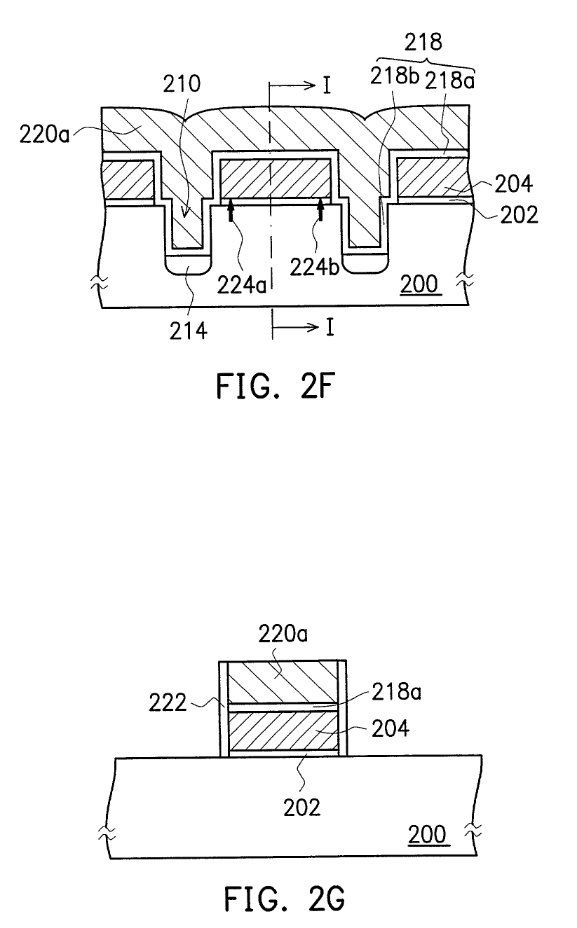

FIGS. 2A to 2F are schematic, cross-sectional views of a flash memory device according to the present invention. FIG. 2G is a cross-sectional view of FIG. 2F along the line I-I.

Referring to FIG. 2A, a gate structure, which comprises a gate oxide layer 202, a floating gate 204, a cap layer 206 and a spacer 208, is formed on the substrate 200. The gate structure is formed by, for example, sequentially forming a dielectric layer (not shown), a conductive layer (not shown) and a dielectric layer (not shown). Photolithography and etching are then conducted to define the dielectric layer, the conductive layer and the dielectric layer to form, respectively, a gate oxide layer 202, a floating gate 204 and a cap layer 206. A dielectric layer is further formed on the substrate 200, followed by performing an etching process, for example, anisotropic etching until the cap layer 206 and the surface of the substrate 200 are exposed to form a spacer 208 on the sidewalls of the gate oxide layer 202, the floating gate 204 and the cap layer 206. The floating gate 204 is, for example, polysilicon. The cap layer is, for example, silicon nitride or silicon oxide, and the spacer 208 is, for example, silicon oxide.

As shown in FIG. 2B, trenches 210 are formed on the two sides of the gate structure in the substrate 200. The trenches 210 are formed by, for example, conducting an anisotropic etching on the substrate 200 while using the cap layer 206 and the spacer 208 as masks. The depth of the trenches 210 is about 0.1 micron to about 1 micron, which is about equal to the channel length of the subsequently formed split gate transistor (a transistor formed with the split-type control gate, a split-type gate dielectric layer and the substrate).

After this, as shown in FIG. 2C, a self-aligned oxidation process is conducted to form a dielectric layer 212 on the exposed substrate 200 surface of the trenches 210, wherein the dielectric layer 212 is, for example, silicon oxide. Using the cap layer 206 and the spacer 208 as masks, an ion implantation is conducted to form source/drain regions 214 in the substrate 200 under a part of the dielectric layer 212 at the bottom of the trenches 210. The ion implantation is accomplished by doping ions vertically into the surface of the substrate 200 under a part of the dielectric layer 212 at the bottom of the trenches 210. The doping energy is about 20 KeV to about 100 KeV. If the implanted dopant is arsenic or phosphorous, the implanted dosage is about 5×10¹⁴ atoms/cm² to about 1.0×10¹⁶ atoms/cm². Furthermore, the source/drain regions can also serve as a buried bit line.

After this, a threshold voltage adjustment implantation is conducted, in which the dopant is implanted at a tilted angle into substrate 200. The dopant for the source/drain region 214 includes boron ions, the doping energy is about 50 KeV and the dosage is about 1×10¹² atoms/cm² to about 5×10¹³ atoms/cm². Since a dielectric layer 212 is formed on the surface of the trenches 210, the exposed substrate 200 in the trenches 210 is prevented from being damaged during the source/drain region implantation and the threshold voltage adjustment implantation.

Continuing to FIG. 2D, the spacer 208, the dielectric layer 212 and the cap layer 206 are removed. When the spacer 208, the dielectric layer 212 and the cap layer are silicon oxide, wet etching is conducted using, for example, an etchant solution containing hydrogen fluoride (HF) to remove these structures. On the other hand, when the spacer 208, the dielectric layer 212 and the cap layer 206 are silicon nitride, wet etching is conducted using, for example, hot phosphoric acid as an etchant.

After this, a conformal dielectric layer 218 is formed on the substrate 200. The dielectric layer includes the inner polysilicon dielectric layer 218a on the top surface and the sidewalls of the floating gate 204, and the split gate dielectric layer 218b on the exposed part of the substrate 200 surface in the trenches 210. The inner polysilicon dielectric layer 218a and the split gate dielectric layer 218b can form concurrently or separately and they can be of different materials. The inner polysilicon dielectric layer 218a is, for example, a silicon oxide-silicon nitride-silicon oxide layer; and the split gate dielectric layer 218b is, for example, polysilicon.

Continuing to FIG. 2E, a conductive layer 220 is formed on the substrate 200, filling the trenches 210 and the spaces between the floating gates.

Referring to FIGS. 2F and 2G, the conductive layer 220 (as in FIG. 2E), the dielectric layer 218, and the floating gate 204 are defined, converting the conductive layer 220 to a control gate 220a. Thereafter, a dielectric layer 222 is formed on the sidewalls of the control gate 220a, the inner polysilicon dielectric layer 218a and the floating gate 204, sealing the floating gate 204 and electrically isolating the floating gate 204. The fabrication of a split-gate flash memory device is thus completed, wherein the split gate transistor is formed with a portion of the control gate 220a above the trench 210, the split gate dielectric layer 218b and the substrate 200.

The operating voltages of the split-gate flash memory device formed according to the preferred embodiment of the present invention are summarized in Table 2.

TABLE 2
The Operating Voltages of the Split-Gate Flash Memory Device Formed
According to the Preferred Embodiment of the Present Invention.

| | Control | Bit Line | | |
|---|---|---|---|---|
| Operations | Gate | (Drain Region) | Source Region | Substrate |
| Programming | 1-10 V | 3-8 V | GND | GND |
| Erasure | GND | GND | GND | >15 V |
| Reading | Vcc | 1-2 V | GND | GND |

Before the performance of the programming operation, the flash memory cell is over-erased and many positive charges are stored in the floating gate 204. During the programming operation, the split gate transistor opens and the hot electrons travel from the source/drain region 214 along the border of the source/drain region 214 to penetrate vertically through the gate oxide layer 202 and inject into the floating gate 204.

Since the source/drain regions and the corresponding floating gate 204 form a symmetrical structure, the probability for hot electrons to travel from the two source/drain regions 214 into the floating gate is equal. As a results, two high electric fields of the channel gaps between the control gate 220a overlying the trenches 210 and the floating gate 204 are provided, resulting in two high hot electron injection points, as indicated by arrows 224a and 224b, formed under the floating gate 204. Consequently, the flash memory device formed according to the present invention provides a lower programming current consumption, a higher electron injection efficiency and an improved operating speed. Furthermore, when compared to the flash memory device of the conventional practice, the programming operation of the flash memory device formed according to the present invention requires a lower operation voltage at the control gate, which is appropriate for the programming operation of 2.5 V and below.

In addition, the depth of the trench is related to and about equal to the channel length of the split gate transistor. As the integration of a device increases and the dimensions of the device decrease, the channel length of the split gate transistor is not affected thereby.

According to the preferred embodiment of the present invention, the formation of the source/drain regions in the exposed substrate 200 at the bottom of the trenches 210 is completed after the formation of the trenches 210 in the exposed substrate 200. The step of forming the trenches 210, in turn, follows the formation of the gate oxide layer 202, the floating gate 204, the cap layer 206 and the spacer 208. Compared to the conventional practice in which the source/drain regions 214 are formed in the substrate 200 before the formation of the floating gate, the fabrication method of the present invention provides a larger processing window and a higher alignment accuracy.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A fabrication method for a flash memory device comprising the steps of:
providing a substrate with a gate structure wherein the gate structure comprises a gate oxide layer, a floating gate is positioned on the gate oxide layer with a cap layer on the floating gate, and a spacer is located on sidewalls of the cap layer, the floating gate and the gate oxide layer;
forming a trench in the substrate on both sides of the gate structure while using the cap layer and the spacer as mask;
forming a first dielectric layer on an exposed substrate surface of the trench;
forming source/drain region in the substrate under a part of the first dielectric layer at a bottom of the trench;
conducting a threshold voltage adjustment implantation;
removing the cap layer, the spacer and the first dielectric layer;
forming a conformal second dielectric layer on the substrate;
forming a conductive layer on the substrate;
defining the conductive layer, the second dielectric layer and the floating gate to convert the conductive layer to a control gate; and
forming a third dielectric layer on sidewalls of the control gate, the second dielectric layer and the floating gate.

2. The fabrication method for a flash memory device according to claim 1, wherein the trench is about 0.1 micron to about 1 micron deep.

3. The fabrication method for a flash memory device according to claim 1, wherein the source/drain region is formed by doping ions vertically into a surface of the substrate to implant ions into the substrate.

4. The fabrication method for a flash memory device according to claim 3, wherein a doping energy is about 20 KeV to about 100 KeV.

5. The fabrication method for a flash memory device according to claim 3, wherein a dosage of the implanted ions is about 5×10¹⁴ atoms/cm² to about 1.0×10¹⁶ atoms/cm².

6. The fabrication method for a flash memory device according to claim 1, wherein a doping energy for the threshold voltage implantation process is about 50 KeV, and a dosage of the implanted ions is about 1×10¹² atoms/cm² to about 5.0×10¹³ atoms/cm².

7. A fabrication method for a flash memory device comprising the steps of:
providing a substrate with a gate oxide layer, a floating gate on the gate oxide layer, a cap layer on the floating gate, and a spacer on sidewalls of the cap layer, the floating gate and the gate oxide layer;
forming a trench in the exposed substrate not covered by the cap layer and the spacer;
forming a source/drain region in the substrate at a bottom of the trench;
removing the cap layer and the spacer;
forming a conformal dielectric layer on the substrate; and
forming a conductive layer on the substrate.

8. The fabrication method for a flash memory device according to claim 7, wherein the trench is about 0.1 micron to about 1 micron deep.

9. The fabrication method for a flash memory device according to claim 7, wherein the source/drain region is formed by doping ions vertically into a surface of the substrate to implant ions into the substrate.

10. The fabrication method for a flash memory device according to claim 9, wherein a doping energy is about 20 keV to 100 KeV.

11. The fabrication method for a flash memory device according to claim 9, wherein a dosage of the implanted ions is about 5×10¹⁴ atoms/cm² to about 1×10¹⁶ atoms/cm².

12. The fabrication method for a flash memory device according to claim 7, wherein after the formation of the source/drain region further includes a performance of a threshold voltage adjustment implantation process.

13. The fabrication method for a flash memory device according to claim 12, wherein a doping energy for the threshold voltage adjustment implantation process is about 50 KeV and a dosage of the implanted ions is about 1×10¹² atoms/cm² to 5.0×10¹³ atoms/cm².

14. A flash memory device comprising:
a substrate, wherein the substrate comprises at least two trenches;
a gate oxide layer, wherein the gate oxide layer is located on the substrate between the trenches;
a floating gate, wherein the floating gate is located on the gate oxide layer;
a plurality of source/drain regions, wherein the source/drain regions are located in the substrate at a bottom of the trenches;
a dielectric layer, wherein the dielectric layer is located on the substrate and the dielectric layer is conformal to the floating gate, the gate oxide layer and the trenches; and
a control gate, wherein the control gate is located on the dielectric layer.

15. The flash memory device according to claim 14, wherein the trenches are about 0.1 micron to 1 micron deep.

16. The flash memory device according to claim 14, wherein the floating gate includes polysilicon.

17. The flash memory device according to claim 14, wherein the control gate includes polysilicon.

18. The flash memory device according to claim 14, wherein the source/drain regions are located at two sides of the floating gate at the bottom of the trenches in the substrate, and the source/drain regions with the corresponding floating gate form a symmetrical structure.
